(19) United States
(12) Patent Application Publication
(10) Pub. No.: US 2003/0229745 A1
(43) Pub. Date: Dec. 11, 2003

(54) Driver for non-volatile solid-state memory

(76) Inventor: Hsuan-Ming Shih, Chung-Li City (TW)

Correspondence Address: TAI GUEN ENTERPRISE CO., LTD., P.O. Box No.6-57, Chung-Ho, Taipei, 235, TW

(21) Appl. No.: 10/163,550

(22) Filed: Jun. 7, 2002

(51) Int. Cl. H05K 7/10; G06F 13/00

(52) U.S. Cl. 710/301

(57) ABSTRACT

A driver for non-volatile solid-state memory is disclosed. The driver comprises an engaging seat body for non-volatile solid-state memory and an electrical interface for data exchange positioned within the seat body, characterized in that the data-exchange electrical interface is connected to the computer main board via conversion circuit. The data exchange interface includes compact flash (CF) card interface, MMC interface or SD card interface or SMC interface or MD card interface or USB interface.

### BACKGROUND OF THE INVENTION

(a) Field of the Invention

The present invention relates to a driver for non-volatile solid-state memory and in particular, a driver for solid-state memory via electrically connection to PC main board. The driver is provided with a function of conversion bus array interface.

(b) Description of the Prior Art

Memory for computer employs magnetic medium to store data. The recently available computer soft disc and hard disc are magnetic medium storage device. Magnetic medium containing storage device facilitates the making of a high capacity memory, however, the longevity of the medium is short and the reliability is low. These are the drawbacks of the magnetic medium.

In all recent available mobile storage device, the object of practical mobile storage device has never been achieved. As a result of large volume of the memory which is not convenient to carry along, for instance, the externally-mounted hard disc, externally-mounted engraving and recording device, ZIP, MO, etc. These devices provide larger storage capacity but they are their mobility is insufficient. If these devices are used as portable memory, for instance, soft disc, a larger space within the specific utilized driver will be taken up, and the energy exhaustion is great, and the noise is high. As the operation speed of the soft disc driver is slow, the storage space is small and the data storage is not reliable. Other than the unsafe characteristics of the magnetic medium as storage medium, and the soft disc is a portable product, physical damages are easily found.

Due to the development of semiconductor technology, the capacity of non-volatile solid-state memory becomes larger and larger but the cost of the memory is decreasing. Under such technological environment, using solid-state memory disc to replace soft disc or hard disc will greatly increase the work reliability and data reliability of the computer. There are numbers of types of memories, such as CF card, MMC, SMA card and other non-volatile solid-state memory having USB interface. These cards are connected via individual interface to PC to proceed with data exchange.

On the other hand, generally, a PC employs hard disc as memory medium, via a hard disc to proceed with guiding operation. In certain situation, customer makes use of soft driver to proceed with guiding operation so as to achieve partial objection, for instance, installation of new system or utilization of non-presently available operating system. Even though, customers may not have the opportunity to use soft disc driver to proceed with guiding operation, but guiding function is one of the basic function, which cannot be ignored. Existing non-volatile solid-state memory simply provides data memory but cannot be used as a guiding device for the system. As a result, drawbacks of application of non-volatile solid-state memory to replace existing driver have not been properly solved.

Further, due to the fact that the structure of each type of card is different, the PC needs to have various types of interfaces in order to satisfy the connection of the above solid-state memory. In this case, the number of the electrical connection interfaces on the PC main board has to be increased, and therefore the housing for the PC will become very complicated. In addition, the position of the interface of the existing solid-state memory is a single position and is always on the PC, this will affect the active application of PC.

### SUMMARY OF THE INVENTION

Accordingly, it is an object of the present invention to provide a driver for non-volatile solid-state memory, which is compatible with other types of solid-state memory driver, and is connected to a computer via a converter and is actively located on a host computer or other externally connected devices.

Yet another object of the present invention is to provide a driver for non-volatile solid-state memory, wherein the inserted solid-state memory thereto can be directly functioned as the guiding disc of the system.

An aspect of the present invention is a driver for non-volatile solid-state storage having seat body for non-volatile solid-state memory and electrical interface for data exchange, characterized in that the data-exchange electrical interface is connected to the computer main board via conversion circuit.

Other objects and advantages of the present invention will become more apparent from the following description taken in conjunction with the accompanying drawing.

### BRIEF DESCRIPTION OF THE DRAWINGS

FIG. 1 is a perspective view of the external structure of the present invention.

FIG. 2 schematically shows the components of the conversion circuit of the non-volatile solid-state memory interface of the present invention.

FIG. 3 is a perspective view showing the mounting of the non-volatile solid-state memory driver onto a host computer in accordance with the present invention.

FIG. 4 is a perspective view showing the mounting of the non-volatile solid-state memory driver onto a monitor in accordance with the present invention.

FIG. 5 is a perspective view showing the mounting of the non-volatile solid-state memory driver onto a keyboard in accordance with the present invention.

FIG. 6 is a perspective view showing the mounting of the non-volatile solid-state memory driver onto a handwriting board in accordance with the present invention.

FIG. 7 is a perspective view showing the mounting of the non-volatile solid-state memory driver onto a mouse in accordance with the present invention.

FIG. 8 is a perspective view showing the mounting of the non-volatile solid-state memory driver onto a voice box in accordance with the present invention.

### DETAILED DESCRIPTION OF THE PRESENT INVENTION

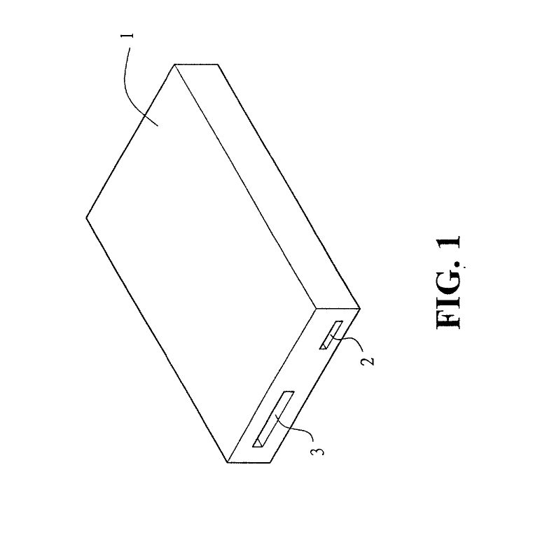

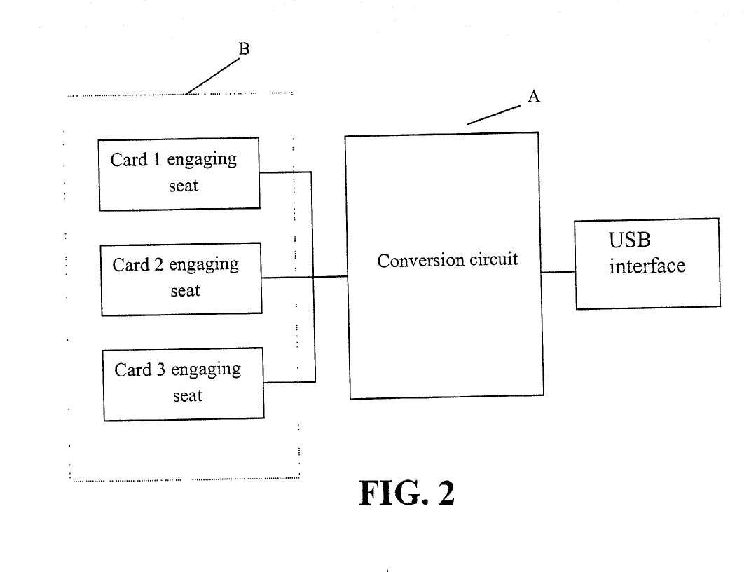

Referring to FIGS. 1 and 2, there is shown a non-volatile solid-state memory driver comprising an engaging seat body 1 and a data exchange electrical interface B within the body 1. The electrical interface B is connected to a computer main board via a conversion circuit A. The data exchange electrical interface B includes CF card interface or MMC interface, or SD card interface, SMC interface, Micro Driver (MD) Card interface or USB interface, etc. The output of the conversion circuit A passes through USB interface C or IEEE 1394 bus array and is then connected to the main board. The conversion circuit comprises CPU, buffer, and bus array signal converter, wherein the bus array signal converter and buffer are respectively connected to CPU junction lines. If the driver includes only the interface seat, the main board provides partial circuit of control and conversion of the memory, or PCI or ISA insertion card provides control or conversion circuit.

The position of one or several types of conversion circuit within the fixed disc driver support IDE/soft disc driver interface USB/IEEE 1394/PCI/ISA interface containing electronic wires can be positioned within the card engaging seat body or the main board. The body 1 for the memory driver is provided with one (or more than one) USB insertion hole 2 and disc type card insertion hole 3.

The following cards can be electrically employed: Compact Flash (CF) card, Smart Media Card, (SMC), Multi-Media Card (MMC), Security Disk (SD), Memory Stick, and USB Flash Disk, and electrical disc (UFD). The output of the conversion circuit passes through USB DP, USB DM of U3 and the main board for communication.

The driver has the function of simultaneously support five cards, MMC, MD, SD, CF, and SMC. The working modes of the above five types of cards are alike. The engaging seat is provided with an inspection for engaged card status and every of each employs a guide leg to inspect the status of the inserted card.

When an inserted card has been detected, data can be accessed card the data is then transmitted. Among the five types of cards, MMC and SD are compatible, and CF and MD are compatible. Thus, there are only three types of engaging seats, as shown in the figure, J1 is USB junction, J3 is CF insertion seat, J2 is SMC insertion seat, and J4 is MMC insertion seat. Three types of cards of such controlling guides are MMC CHK, SMC CD, and CF CD. Other than the working voltage of main chip and partial circuit of CF card being DC 5V, the working voltage of other partial circuit is DC 3.3V.

In accordance with the present invention, U1, U5 are 8-bit bus array signal converter. That is, 5V signal and 3.3 V signal can be inter-converted so as to facilitate the main chip and the CF card to communicate with other sections. U2, U4 are two buffers used to proceed with data locking and storage control. In the conversion circuit, three types of engaging seats respectively employ MMC CHK, SMC CD, and CF CD control guide to monitor the insertion status of the cards. Before the card is inserted, the guide is at high electrical frequency, and when a card is inserted to the corresponding seat, the control pin is changed to low electric frequency and an inserted card is being detected. At this instance, data is accessed from the card, and by way of the data line, the data is transmitted.

CF card: Due to fact that the CF possesses data storage function, U3 employs three address lines CF-A0, CF-A1, CF-A2 to control address selection of J3 CF card, and employs CF, #RE, ST9-#WE network to control card read-write operation, and employs CF R/B pin to determine whether card operation status is Ready or Busy. Finally, eight data lines ST9-DO-ST9-D7 are used to proceed with data transmission.

MMC: The data transmission format of MMC is series data transmission, and MMC-CLK receives clock signal, and MMC-DAT pins receive data signals. Due to the influence of transmission format, the signal and data cannot pass through U3 for reception directly. Thus, U2 and U4 are used to proceed with data buffering and storage.

SMC: The data transmission format of SMC is parallel data transmission. U1, U5 are employed for controlling of signals with U3 and the locking and storage of parallel data signal and transmission. In the circuit, U1 is used as control signal receiving and transmitting device. U5 is used as data receiving and the Network ST9-DATA DIR from U3 controls transmitting device, and passage of the signal thereof. When this signal has not been triggered, the data are locked and stored. When this signal is triggered, the data is transmitted and the format of data transmission is bidirectional.

When the non-volatile solid-state memory is used as guiding disc, the driving section is located on the main board and can also be located within the driver. When the memory is inserted at the computer after it passes the driver, inspect the settings of the switching ON sequence, and enter the optic driver or soft disc driver.

BIOS generates inquiry signal to the driver junction to inquire the device format on the driver junction. When the device responds as a standard device, BIOS adjusts internal established standard device to initiate the program. Then, the driver can be set as standard guide device.

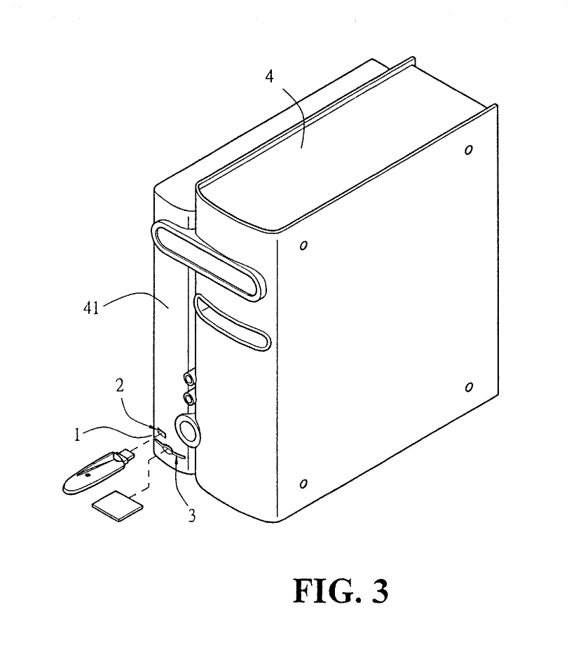

Referring to FIGS. 3 to 8, there is shown the mounting of the driver on the computer and on other externally connected device.

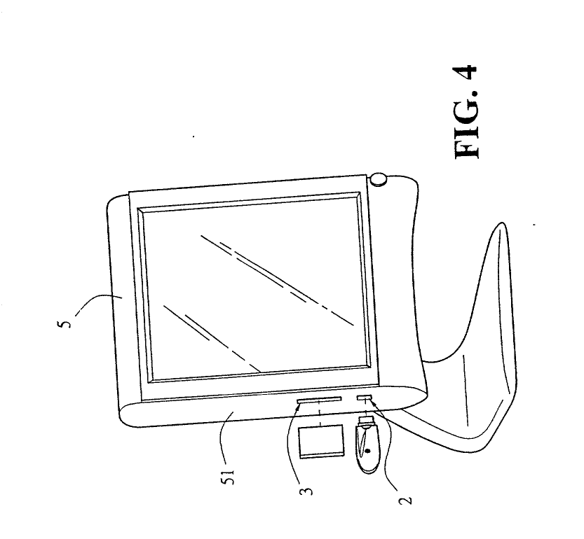

Referring to FIGS. 3 and 4, the engaging seat body 1 is positioned on the host device 4 or a display 5, wherein the engaging seat body includes two separately mounted insertion holes, for instance USB insertion hole 2, disc-type insertion hole 3. The engaging seat body 1 is positioned on the operation and control panel 41 of the host device 4, or is located on the lateral side proximity to the lower section 51 of the display 5 so as to facilitate insert or dial out operation. Besides, it can also be directly mounted on the housing of the computer, for instance, on the keyboard or mouse or handwriting board or voice box. These externally connected devices are provided with USB interface for connection with host which can fully support data exchange of the driver.

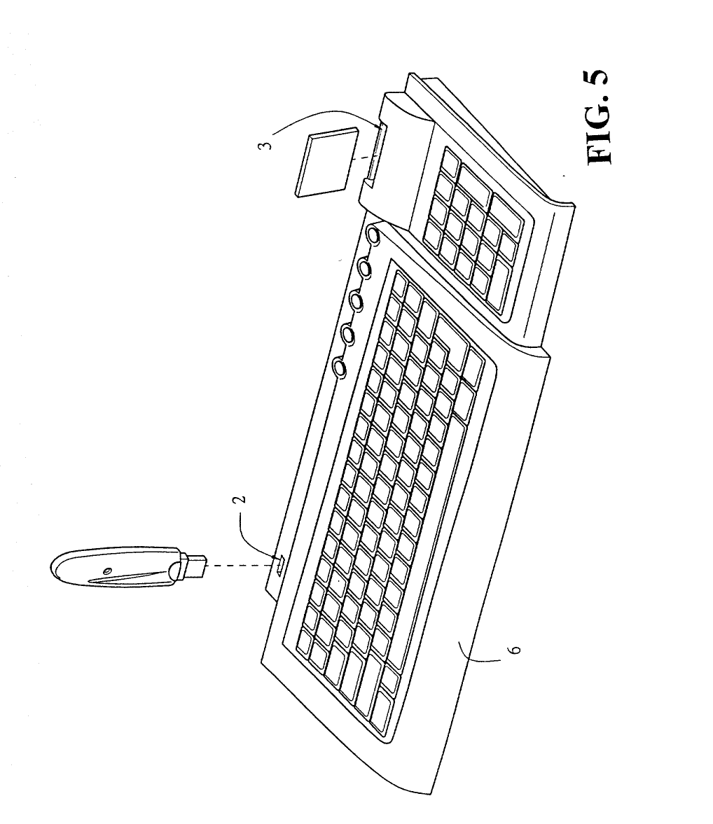

Referring to FIG. 5, the driver is located on the keyboard 6, the two insertion holes of the engaging seat body are separately mounted, for instance, USB insertion hole 2, and disc-type insertion hole 3. The direction of insertion is from the top to the bottom, and from the front to the rear, and from the rear to the front, and from the left to the right, or from the right to the left.

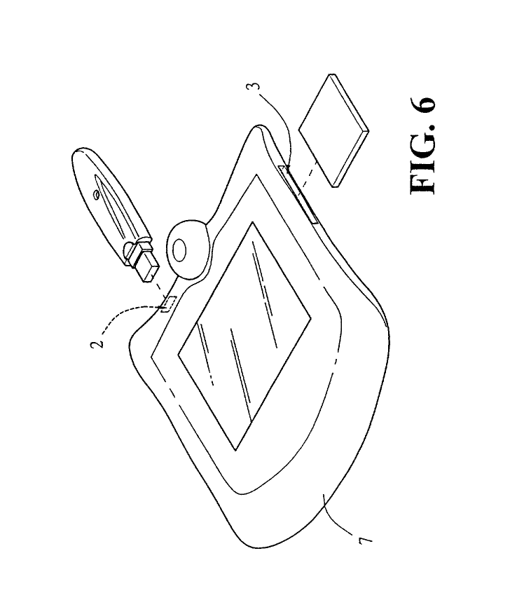

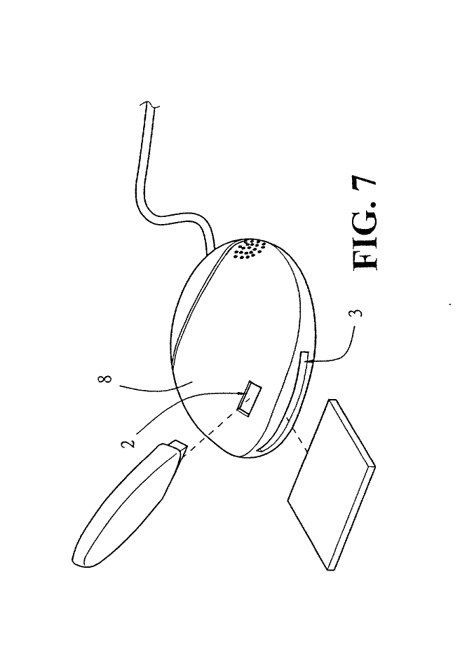

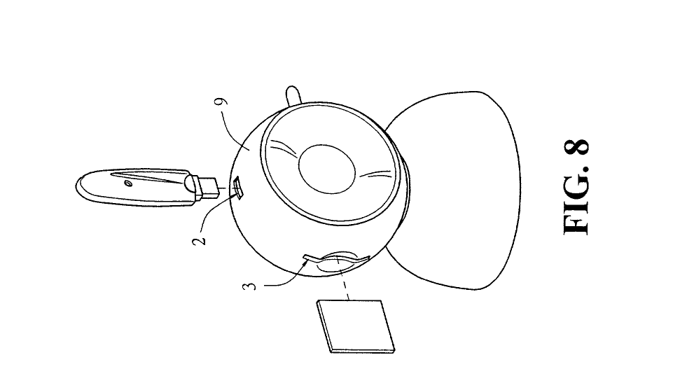

Referring to FIG. 6, there is shown the driver being positioned on the handwriting board. FIG. 7 shows the driver 1 being located on the mouse. FIG. 8 shows the driver being mounted on the voice box, wherein the insertion holes of the engaging seat body are two separately positioned holes, i.e., USB insertion hole 2, and disc-type insertion bole 3.

In accordance with the present invention, the insertion hole of the engaging seat body, either one or more than one, either integrally mounted or separately mounted, the conversion circuit or the driving circuit of the driver is one, which can be used as a module, where the circuit being externally mounted on the keyboard. It can also integrate with an externally mounted circuit of the keyboard together to form as being an integrated chip. The interface can be USB or IEEE 1394. The concept of circuit arrangement is the same in other preferred embodiment. The memory inserted onto the driver can be one or more than one of the following components:

a. Compact Flash Card

b. Smart Media Card

c. MultiMedia Card

d. USB Flash Card

In application, after a memory has been chosen and is used to support other type of memory passed through converter to convert into the type of memory, the functions thereof are totally the same.

In accordance with the present invention, the advantages are as follows:

(1) The present invention can proceed with various operation with respect to nonvolatile solid-state memory, for instance, formatting, write, copy and document erase prevention. The present driver also provides the uniqueness of memory medium.

(2) After a nonvolatile solid-state memory interface standard is selected, using a converter for one USB to another USB, the memory card of other interface can be converted to other storage device which allows the visiting by fixed disc driver by mean of a standard device interface.

(3) When a nonvolatile solid-state memory is provided with guide driving function, the present driver can be used as a converter having strong compatibility for various kinds of nonvolatile solid-state memories.

(4) The present driver has the characteristics of low cost and high capacity and can proceed with the guiding operation without an operation system.

(5) As a result of having no mechanical operation device as that of the disc-reading device, the driver can be actively mounted to the host computer, display or other devices mounted externally, and based on the needs of the customer, more than one insertion hole can be incorporated.

While the invention has been described with respect to preferred embodiments, it will be clear to those skilled in the art that modifications and improvements may be made to the invention without departing from the spirit and scope of the invention. Therefore, the invention is not to be limited by the specific illustrative embodiment, but only by the scope of the appended claims.

I claim:

1. A driver for non-volatile solid-state storage having engaging seat body for non-volatile solid-state memory and electrical interface for data exchange, characterized in that the data-exchange electrical interface is connected to the computer main board via conversion circuit.

2. The driver for non-volatile solid-state storage of claim 1, wherein the data exchange interface includes compact flash (CF) card interface, MMC interface or SD card interface or SMC interface or MD card interface or USB interface.

3. The driver for non-volatile solid-state storage of claim 1, wherein the output of the conversion circuit is connected to the main board via USB or IEEE 1394 bus array.

4. The driver for non-volatile solid-state storage of claim 1, wherein the conversion circuit includes CPU, buffer, bus array signal converter, and the buffer and bus array signal converter are respectively connected to CPU junction line.

5. The driver for non-volatile solid-state storage of claim 1, wherein the conversion circuit is connected to a driving guide device.

6. The driver for non-volatile solid-state storage of claim 1, wherein the conversion circuit is mounted within the seat body or on the main board.

7. The driver for non-volatile solid-state storage of claim 1, wherein the seat body is provided with one or more than one insertion hole.

8. The driver for non-volatile solid-state storage of claim 7, wherein more than one insertion hole are remotely mounted.

9. The driver for non-volatile solid-state storage of claim 1, or 7 or 8, wherein the seat body is mounted on the host computer or the display or to externally connected device.

10. The driver for non-volatile solid-state storage of claim 9, wherein the externally connected device at least includes keyboard, or mouse or handwriting board or voice box.
